(19) United States
(12) Patent Application Publication
(10) Pub. No.: US 2018/0375054 A1
(43) Pub. Date: Dec. 27, 2018

(54) FLEXIBLE DISPLAY SCREEN AND DISPLAY APPARATUS COMPRISING THIS FLEXIBLE DISPLAY SCREEN

(71) Applicant: BOE Technology Group Co., Ltd., Beijing (CN)

(72) Inventors: Wei Wang, Beijing (CN); Jingkai Ni, Beijing (CN)

(73) Assignee: BOE Technology Group Co., Ltd., Beijing (CN)

(21) Appl. No.: 15/579,768

(22) PCT Filed: Jun. 8, 2017
(86) PCT No.: PCT/CN2017/087589

§ 371 Date: Dec. 5, 2017

(30) Foreign Application Priority Data
Aug. 30, 2016 (CN) 201610763889.8

(51) Int. Cl. H01L 51/52; H01L 51/00

(52) U.S. Cl. CPC H01L 51/524; H01L 51/5281; G09F 9/301; H01L 51/0097; H01L 51/5253

(57) ABSTRACT

This disclosure proposes a flexible display screen comprising a display screen and a film located on a back side opposite to a display side of the display screen, wherein this film is magnetic. This disclosure further relates to a display apparatus comprising this flexible display screen.

### CROSS-REFERENCE TO RELATED APPLICATION

This application is a Section 371 National Stage Application of International Application No. PCT/CN2017/087589, filed Jun. 8, 2017, which has not yet been published, and claims the priority of Chinese Patent Application No. 201610763889.8 filed on Aug. 30, 2016, the contents of which are incorporated as a part of this application by reference in their entirety.

### FIELD OF THE INVENTION

This disclosure relates to a flexible display screen, and further relates to a display apparatus comprising the flexible display screen, and an accommodating device.

### BACKGROUND OF THE INVENTION

At present, flexible display screens are mainly used for fixed deformation. For example, there has been such a design that a flexible display screen is fixed on the back side of a rigid cover glass. This design has lower requirements for the encapsulating material on the back side of the flexible display screen and the encapsulating method, and the object of protecting the flexible display screen can be achieved by using an ordinary protective material.

### SUMMARY OF THE INVENTION

According to a first aspect of this disclosure, there is provided a flexible display screen, comprising a display screen located on a display side (i.e., a side for display) and a film located on a back side opposite to the display side, wherein the film is magnetic.

Thus, the flexible display screen is allowed to have magnetism in a simple manner.

Optionally, the film may comprise a base thin film and a magnetic layer on the base thin film so as to provide magnetism for the film. The magnetic layer may be a magnetic powder coating layer or a magnet coating layer.

Optionally, the film may also comprise a material mixed with magnetic powders. This material may be PET (polyethylene terephthalate) or PEN (polyethylene naphthalate).

Optionally, the film may comprise an adhesive layer, and the adhesive layer is used for fixing the film to the back side of the flexible display screen.

Optionally, the display screen comprises a polarizer, a TFE layer, an OLED layer, and a PI substrate.

According to a second aspect of this disclosure, there is provided a display apparatus comprising a flexible display screen, comprising a display screen and a film located on a back side opposite to a display side of the display screen, wherein the film is magnetic.

Optionally, this display apparatus further comprises a supporting member being configured to match the flexible display screen by magnetic adsorption effect.

Optionally, the supporting member may comprise a rigid plate, and the rigid plate is ferrous or magnetic, so that the flexible display screen in the expanded state can maintain flatness by means of the rigid plate.

Optionally, the supporting member may comprise a flexible plate, and the flexible plate is magnetic. Thus, the flexible display screen leans on the flexible plate by magnetic adsorption effect.

Optionally, the supporting member may comprise a roller, and the roller is magnetic so that this flexible display screen leans on the roller when the flexible display screen is rolled up.

Optionally, the supporting member may further comprise a housing having an opening for taking in the flexible display screen, wherein the roller may pivot on this housing.

Optionally, the housing may be transparent, and the flexible display screen may be arranged so that: the display side of this flexible display screen in a rolled-up state faces toward the outside of the display apparatus along the radial direction of the roller and therefore the display side of the flexible display screen is visible outside the housing.

According to a third aspect of this disclosure, there is provided an accommodating device for accommodating a magnetic flexible display screen, comprising a housing and a roller, wherein the roller is magnetic so as to roll up the magnetic flexible display screen on the roller by magnetic adsorption effect.

Optionally, the roller pivots on the housing.

Optionally, the roller has a magnetic coating layer.

Optionally, the housing has an opening for taking in the magnetic flexible display screen.

### BRIEF DESCRIPTION OF THE DRAWINGS

The embodiments of this disclosure will be illustrated in detail below with reference to accompanying drawings, in which:

FIG. 1 is a schematic sectional view illustrating a deformable flexible screen, wherein undesirable curling of the flexible screen occurs in the expanded state;

FIG. 2 is a schematic sectional view illustrating a flexible display screen according to one preferable embodiment of this disclosure and a display apparatus comprising this flexible display screen, wherein the flexible display screen is in the expanded state;

FIG. 3 is a schematic sectional view illustrating the display apparatus as shown in FIG. 2, wherein the flexible display screen is in the rolled-up state;

FIG. 4 is a schematic sectional view illustrating a display apparatus according to another preferable embodiment of this disclosure; and

FIG. 5 is a schematic sectional view illustrating the composition of a display screen according to one preferable embodiment of this disclosure.

### DETAILED DESCRIPTION OF THE INVENTION

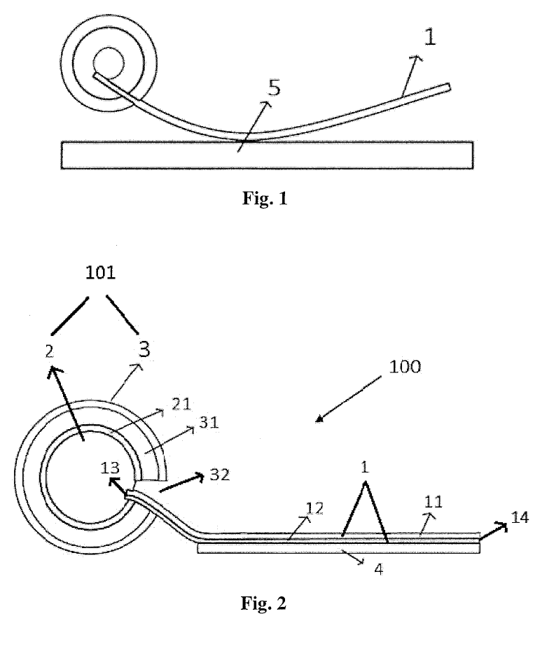

FIG. 1 is a schematic sectional view illustrating a deformable flexible screen. When a deformable flexible display screen 1 is used, the flexible display screen 1 will be not stably maintained on a desktop 5 and various curling phenomena will easily occur, and this is not convenient for use and operation.

Thus, it is desirable to improve the stability of the display apparatus comprising the flexible display screen and reduce and eliminate the curling phenomenon of the flexible display screen.

FIG. 2 illustrates a flexible display screen according to one preferable embodiment of this disclosure and a display apparatus comprising this flexible display screen. As shown in FIG. 2, the display apparatus 100 comprises a flexible display screen 1, and this flexible display screen 1 is composed of a display screen 11 located on a display side and a film 12 located on a back side opposite to the display side, wherein the film 12 is magnetic. Thus, the film 12 not only has the protective effect on the flexible display screen 1, but also allows it to have magnetism. Therefore, the flexible display screen 1 which is magnetic can cooperate with a matched supporting member which is magnetic by magnetic adsorption effect so as to improve the stability of the flexible display screen 1.

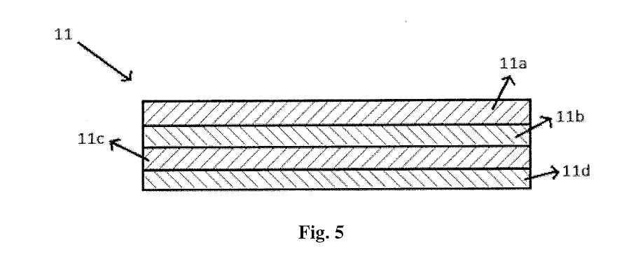

For example, the display screen 11 may comprise a polarizer 11a, a TFE (thin film encapsulation) layer 11b, an OLED (organic light-emitting diode) layer 11c, and a PI (polyimide) substrate 11d, as shown in FIG. 5.

The film 12 may be composed of a base thin film and a magnetic layer on the base thin film. The magnetic layer may be a magnetic powder coating layer or a magnet coating layer. Optionally, the film 12 may also be produced by mixing a PET (polyethylene terephthalate) or PEN (polyethylene naphthalate) material with magnetic powders. The film 12 may further comprise an adhesive layer, which is used for evenly binding the film 12 to the back side of the flexible display screen 1.

FIGS. 2 to 4 illustrate different embodiments of a supporting member. As shown in FIG. 2, a rigid plate 4, which is ferrous or magnetic, may be used as a supporting member. It can be contemplated that when the rigid plate 4 is magnetic, the flexible display screen 1 in the expanded state may lean on the rigid plate 4 by magnetic adsorption effect so that the expanded flexible display screen can maintain flatness. The stability is improved and the occurrence of undesirable curling is avoided.

As shown in FIG. 4, a flexible plate 4′, which is magnetic, may also be used as a supporting member. Thus, the flexible display screen 1 leans on the flexible plate 4′ by magnetic adsorption effect. Therefore, the flexible display screen 1, which is expanded and placed on a desktop 5, has a certain rigidity so as not to be uncontrollably and arbitrarily curled, and also has a certain flexibility so as to be capable of performing desirable deformation as needed. It can be contemplated that the flexible display screen 1, which is magnetic, may be fixed on the flexible plate 4′, for example, in a manner of adhesion and the like. Of course, the connection of the flexible display screen 1 and the flexible plate may be achieved in other manners. For example, the flexible display screen 1 is allowed to lean on the flexible plate 4′ only when being used, and it may be separated and removed from the flexible plate 4′ when not being used.

With reference to FIGS. 2 to 4, the display apparatus 100 may comprise a roller 2. This roller may be ferrous or magnetic so that the back side of the flexible display screen 1 is attracted and leans on the surface of the roller 2 due to the magnetic adsorption effect when the flexible display screen 1 is rolled up (for example, the roller 2 is rotated counter-clockwise in the state as shown in FIG. 2). Thus, the roller 2 may be used as the supporting member which matches the flexible display screen 1, and the flexible display screen 1 is allowed to comply with the surface of the roller so as to roll up and contain the flexible display screen 1. Therefore, the stability of the flexible display screen 1 in the rolled-up state is improved. It can be contemplated that a magnetic coating layer or a magnetism roller sleeve 21 may be coated or bonded onto the surface of the roller 2.

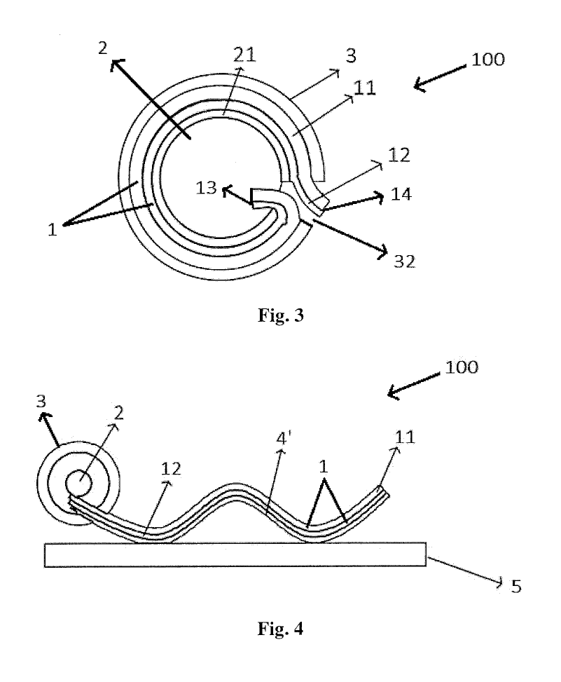

As shown in FIG. 3, the supporting member may further comprise a housing 3, and this housing has an opening 32 for the flexible display screen 1 so that the flexible display screen 1 protrudes from this opening 32 and is expanded. The roller 2 may pivot on the housing 3. Therefore, in the state as shown in FIG. 3, it is possible to pull the flexible display screen 1 outwards from the opening 32 and allow the roller 2 to rotate along the clockwise direction to expand the flexible display screen 1. When rolling up the flexible display screen 1, the flexible display screen 1 is rolled up and contained in a storage space 31 of the housing 3, so that this flexible display screen 1 can be better protected.

As shown in FIG. 2, an accommodating device 101 may comprise a roller 2. This roller may be ferrous or magnetic so that the back side of the flexible display screen 1 is attracted and leans on the surface of the roller 2 due to the magnetic adsorption effect when the flexible display screen 1 is rolled up (for example, the roller 2 is rotated counter-clockwise in the state as shown in FIG. 2). Thus, the roller 2 may be used as the supporting member which matches the flexible display screen 1, and the flexible display screen 1 is allowed to comply with the surface of the roller so as to roll up and contain the flexible display screen 1. Therefore, the stability of the flexible display screen 1 in the rolled-up state is improved. It can be contemplated that a magnetic coating layer or a magnetism roller sleeve 21 may be coated or bonded onto the surface of the roller 2. Additionally, the accommodating device 101 may further comprise a housing 3, and this housing has an opening 32 for the flexible display screen 1 so that the flexible display screen 1 protrudes from this opening 32 and is expanded. The roller 2 may pivot on the housing 3. Therefore, in the state as shown in FIG. 3, it is possible to pull the flexible display screen 1 outwards from the opening 32 and allow the roller 2 to rotate along the clockwise direction to expand the flexible display screen 1. When rolling up the flexible display screen 1, the flexible display screen 1 is rolled up and contained in a storage space 31 of the housing 3, so that this flexible display screen 1 can be better protected.

As shown in FIGS. 2 and 3, a fixed end 13 of the flexible display screen 1 is fixed together with the roller 2. When being used, a free end 14 of the flexible display screen 1 may be drawn, so that it protrudes outwards from the opening 32 and is expanded.

Particularly, the housing 3 may be transparent, and the flexible display screen 1 may be arranged so that: the display screen 11 of the flexible display screen 1 in the rolled-up state faces toward the outside of the display apparatus along the radial direction of the roller 2 and therefore the display screen 11 is visible outside the housing 3, as shown in FIG. 3. Thus, the display apparatus 100 may also display images or perform lighting in the rolled-up state.

The display apparatus of this disclosure has been illustrated above by embodiments. It is to be indicated that the illustration above is merely exemplary, and various modifications and variations may be made to embodiments of this disclosure by the person skilled in the art according to the illustration described above. These modifications and variations are all within the scope protected by this disclosure.

1. A flexible display screen, comprising a display screen and a film located on a back side opposite to a display side of the display screen, wherein the film is magnetic.

2. The flexible display screen according to claim 1, wherein the film comprises a base thin film and a magnetic layer on the base thin film.

3. The flexible display screen according to claim 2, wherein the magnetic layer is a magnetic powder coating layer or a magnet coating layer.

4. The flexible display screen according to claim 1, wherein the film comprises a material mixed with magnetic powders.

5. The flexible display screen according to claim 4, wherein the material is polyethylene terephthalate or polyethylene naphthalate.

6. The flexible display screen according to claim 1, wherein the film comprises an adhesive layer for fixing the film to the back side of the flexible display screen.

7. The flexible display screen according to claim 1, wherein the display screen comprises a polarizer, a TFE layer, an OLED layer, and a PI substrate.

8. A display apparatus comprising a flexible display screen, comprising a display screen and a film located on a back side opposite to a display side of the display screen, wherein the film is magnetic.

9. The display apparatus according to claim 8, wherein the display apparatus further comprises a supporting member being configured to match the flexible display screen by magnetic adsorption effect.

10. The display apparatus according to claim 9, wherein the supporting member comprises a rigid plate which is magnetic.

11. The display apparatus according to claim 9, wherein the supporting member comprises a flexible plate which is magnetic.

12. The display apparatus according to claim 9, wherein the supporting member comprises a roller which is magnetic so that the flexible display screen leans on the roller when the flexible display screen is rolled up.

13. The display apparatus according to claim 12, wherein the supporting member further comprises a housing having an opening for taking in the flexible display screen, wherein the roller pivots on the housing.

14. The display apparatus according to claim 13, wherein the housing is transparent, and the flexible display screen is arranged so that: the display side of the flexible display screen in a rolled-up state faces toward the outside of the display apparatus along the radial direction of the roller and therefore the display side of the flexible display screen is visible outside the housing.

15. An accommodating device for accommodating a magnetic flexible display screen, comprising a housing and a roller, wherein the roller is magnetic so as to roll up the magnetic flexible display screen on the roller by magnetic adsorption effect.

16. The accommodating device according to claim 15, wherein the roller pivots on the housing.

17. The accommodating device according to claim 15, wherein the roller has a magnetic coating layer.

18. The accommodating, device according to claim 15, wherein the housing has an opening for taking in the magnetic flexible display screen.
